(19) United States
(12) Patent Application Publication
(10) Pub. No.: US 2026/0370139 A1
(43) Pub. Date: Nov. 19, 2026

(54) NON-INTEGER MULTISTAGE CHARGE PUMP

(71) Applicant: GlobalFoundries U.S. Inc., Malta, NY (US)

(72) Inventors: Siva Kumar Chinthu, Bangalore (IN); Suresh Pasupula, Bangalore (IN); Alok Kumar Mishra, Bangalore (IN)

(21) Appl. No.: 19/207,871

(22) Filed: May 14, 2025

(51) Int. Cl. H02M 3/07; G11C 5/14

(52) U.S. Cl. CPC H02M 3/07; G11C 5/145

(57) ABSTRACT

Structures and methods of a non-integer multistage charge pump are disclosed. A structure of the disclosure includes a plurality of non-final charge pump stages coupled in series, wherein each of the non-final charge pump stages are coupled to a continuous clock; and a final charge pump stage coupled in series to the plurality of non-final charge pump stages, wherein the final charge pump stage is coupled to a modulated clock generated from a feedback control circuit, wherein the feedback control circuit generates the modulated clock from an output of the final charge pump stage, a reference voltage, and the continuous clock.

### BACKGROUND

The present disclosure relates to a structure with a non-integer multistage charge pump and a related method.

A charge pump circuit is a circuit that converts an input voltage to a higher voltage. Multistage charge pumps include a series of stages in which each stage increases the voltage, thus allowing the circuit to generate substantially higher voltages relative to the input voltage. Each stage of the circuit operates by sequentially charging and discharging capacitors, effectively pumping charge across each stage to achieve a desired voltage conversion.

### SUMMARY

Aspects of the disclosure provide a multistage charge pump that utilizes a feedback control circuit to control just the final stage of the multistage charge pump to achieve non-integer voltage values and reduced capacitor sizes.

Further aspects of the disclosure provide a structure having: a plurality of non-final charge pump stages coupled in series, wherein each of the non-final charge pump stages are coupled to a continuous clock; and a final charge pump stage coupled in series to the plurality of non-final charge pump stages, wherein the final charge pump stage is coupled to a modulated clock generated from a feedback control circuit, wherein the feedback control circuit generates the modulated clock from an output of the final charge pump stage, a reference voltage, and the continuous clock.

Additional aspects of the disclosure provide a method including: receiving a voltage input (Vin) at multistage charge pump having a plurality of non-final charge pump stages and a final charge pump stage, wherein the plurality of non-final charge pump stages and final charge pump stage are serially connected; increasing a voltage at each stage n of the plurality of non-final charge pump stages according to a formula (n+1)Vin and outputting an increased voltage N*Vin to the final charge pump stage where N-1 is a number of non-final charge pump stages, wherein each non-final stage is coupled to a continuous clock; increasing the voltage at the final charge pump stage with a fractional voltage R*Vin where R is any value between 0 and 1, wherein the final charge pump stage is coupled to a modulated clock generated by a feedback control circuit, and wherein the feedback control circuit generates the modulated clock from an output of the final charge pump stage, a reference voltage, and the continuous clock; and outputting the voltage N*Vin + R*Vin.

It should be noted that all aspects, examples, and features of disclosed embodiments mentioned in the summary above can be combined in any technically possible way. That is, two or more aspects of any of the disclosed embodiments, including those described in this summary section, may be combined to form implementations not specifically described herein. The details of one or more implementations are set forth in the accompanying drawings and the description below. Other features, objects and advantages will be apparent from the description and drawings, and from the claims.

### BRIEF DESCRIPTION OF THE DRAWINGS

The present disclosure will be better understood from the following detailed description with reference to the drawings, which are not necessarily drawn to scale and in which:

FIG. 1 is a schematic diagram of multistage charge pump according to embodiments of the disclosure.

FIG. 2 is a timing diagram showing operation of the multistage charge pump of FIG. 1 according to embodiments of the disclosure.

### DETAILED DESCRIPTION

A charge pump circuit is a circuit that converts a direct current (DC) power source, e.g., an input voltage (Vin) to a larger DC output voltage. A multistage charge pump utilizes a series of stages to increase the voltage in a stepwise fashion. For example, a first stage might output a voltage of 2*Vin, a second stage might output 3*Vin, a third stage might output 4*Vin, etc. Accordingly, each stage outputs integer increments of the input voltage according to formula (n+1)Vin, where n is the stage’s position. However, in certain applications, the desired output might not be an integer increment of the input voltage Vin. For example, the multistage charge pump might include five stages having an input voltage Vin supplied to the first stage of 2 volts, which therefore outputs 12 volts. However, the application might require an output voltage of 11.3 volts. To achieve this, a non-integer multistage charge pump is provided, which can be implemented with low area and high efficiency.

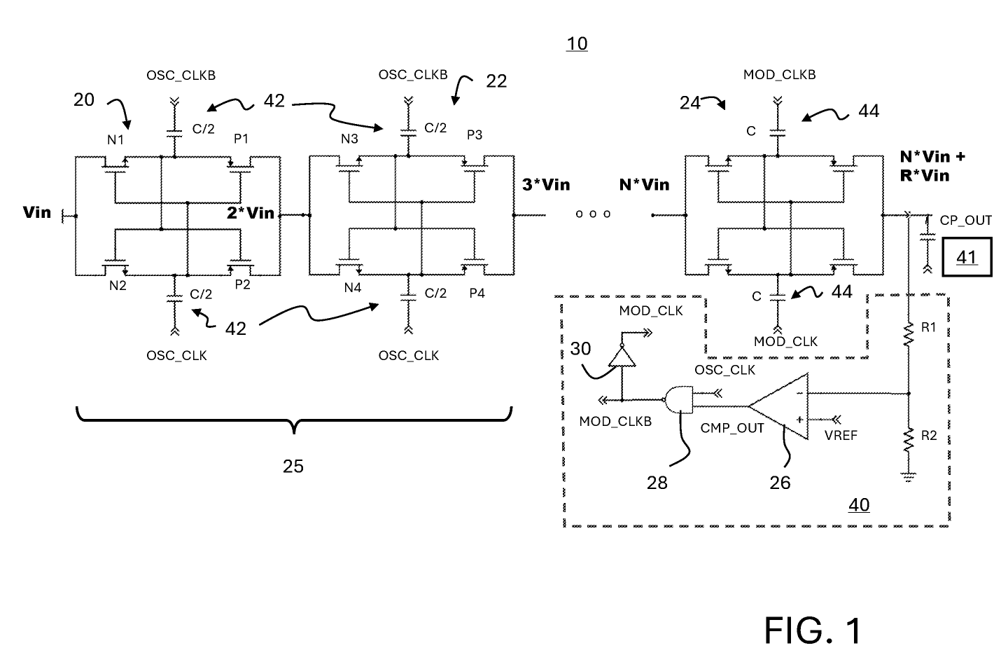

FIG. 1 depicts an illustrative non-integer multistage charge pump 10, which may for example be implemented in a structure such as an integrated circuit, including memory circuits such as flash memory. In certain embodiments, the output of charge pump 10 may be coupled to one or more memory cells 41. Charge pump 10 includes an array of serially connected stages, 20, 22 … 24, which generally comprises a final stage 24 and a plurality of non-final stages 25. Charge pump receives as input voltage Vin, which can for example comprise a supply voltage Vdd (e.g., 1.8 volts). Additionally, a system clock is provided by a clock generator (not shown) that provides continuous clock (OSC_CLK), e.g., having a 1.8 voltage swing. As can be seen, each of the non-final stages 25 incrementally increases the voltage according to the formula (n+1)Vin (where n is the stage number), such that the output of a first stage 20 is 2*Vin, the output of a second stage 22 is 3*Vin, and the output of the last non-final stage is N*Vin (where N is the final stage number). The final stage 24 however does not incrementally increase the voltage, but instead adds a fractional amount of voltage R*Vin, which generally can include any voltage value between 0 and Vin. Accordingly, the charge pump output (CP_OUT) outputs a voltage value N*Vin + R*Vin, i.e., a non-integer result.

To implement this feature, charge pump 10 includes a feedback control circuit 40 that generates a modulated clock (MOD_CLK) and inverted modulated clock (MOD_CLKB) to drive the final stage 24. Conversely, each of the non-final stages 25 are driven by the continuous clock (OSC_CLK) and inverted continuous clock (OSC_CLKB). Accordingly, the final charge pump stage 24 is coupled to modulated clocks generated from feedback control circuit 40, whereas the non-final charge pump stages 25 are not coupled to the feedback control circuit 40. This arrangement provides faster operations as the feedback only controls the final stage 24.

In this illustrative embodiment, feedback control circuit 40 includes a voltage divider (e.g., a pair of series resistors R1, R2 connected between CP_OUT and ground and having an output node therebetween), a comparator 26, a NAND gate 28, and an inverter 30 to generate the modulated clocks. As shown, the first resistor R1 is coupled between CP_OUT and the output node (i.e., the input of the comparator 26) and the second resistor R2 is coupled between the output node (i.e., the input of the comparator 26) and ground. The output node of R1 and R2 is used to reduce the voltage at the negative terminal input of comparator 26. For example, if VREF is 0.6V and the charge pump output (CP_OUT) is significantly higher (e.g., over 10V), R1 and R2 can be used to reduce the middle point of the two resistors into the 0.6V range.

Feedback control circuit 40 uses the divided voltage (obtained from an output of the final charge pump stage CP_OUT), a reference voltage VREF, and the continuous clock OSC_CLK to generate the modulated clocks MODCLK and MODCLKB. Operation of the feedback control circuit 40 is as follows. Comparator 26 generates a compare signal CMP_OUT from the divided voltage (derived from CP_OUT) and VREF, which for example comprises a difference between the two signals. VREF is selected to achieve a desired output (e.g., 11.3 volts) of the charge pump 10. The output of comparator 26 (CMP_OUT) is thereafter inputted to a logic gate arrangement that generates the modulated clock (MOD_CLK) and the inverted modulated clock (MOD_CLKB) from the compare signal CMP_OUT and the continuous clock OSC_CLK. In this case, the logic arrangement includes NAND gate 28 that generates MOD_CLKB from the inputs CMP_OUT and OSC_CLK. Inverter 30 then generates the MOD_CLK from MOD_CLKB. The feedback control circuit 40 accordingly will provide Process, Voltage, and Temperature (PVT) compensation to control the amount of non-integer voltage generated by the final stage 24, regardless of PVT fluctuations to the input (N*Vin) of the final stage.

In the illustrative embodiment, VREF is 0.6V (e.g., generated from a bandgap reference circuit) and the comparator 26 turns ON when the output voltage discharges towards 1.75 V at the negative terminal of comparator 26 (with the middle node between R1 and R2 being at 0.6V – 15mV), and turns OFF when the output voltage charges towards 1.85V at the negative terminal of comparator 26 (with the output node between R1 and R2 being at 0.6V + 15mV). Accordingly, based on the output voltage, the negative terminal follows the output voltage with a scaling towards VREF +/- 15mV. The comparator output modulates the continuous clock (OSC_CLK) to MOD_CLK/MOD_CLKB with an ON/OFF clock cycle ratio (R), which is the fraction of VDDW to be added by the final stage to maintain the final voltage constant at +1.8V ± 50mV. The ratio, R, depends on the variation gap of N * Vin from the final voltage N*Vin + R*Vin, which is corrected by the comparator output duty cycle. The MOD_CLK/MOD_CLKB ON/OFF clock cycles are automatically adjusted by the control system 40 with respect to the constant VREF = 0.6V.

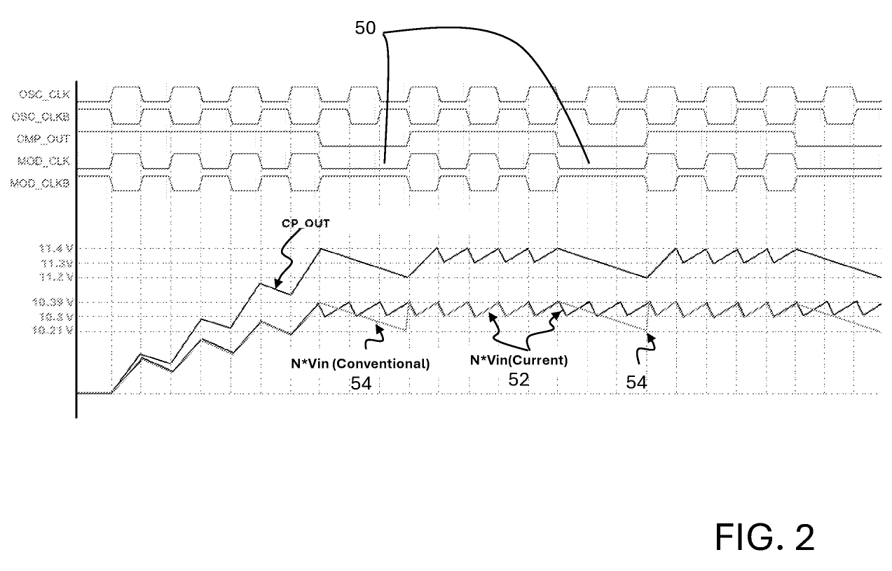

FIG. 2 depicts a timing diagram, which at the top, shows an example of the output of comparator 26 (CMP_OUT), continuous clocks (OSC_CLK/OSC_CLKB), and modulated clocks (MOD_CLK/MODCLOCKB). As can be seen, MOD_CLK is modulated (i.e., made non-continuous) with gaps 50 based on CMP_OUT. The bottom section of the timing diagram shows CP_OUT. Controlling the gaps 50 in turn controls the output signal CP_OUT, i.e., the greater the gaps 50, the lower the voltage output CP_OUT, and vice versa. Also shown on the bottom of the timing diagram is an example of N*Vin (i.e., the input to the final stage) using the current technique 52 and N*Vin using a conventional technique 54.

A feature of this approach is that because the feedback control circuit 40 is only coupled to the final stage 24 (FIG. 1), smaller capacitors can be utilized in the non-final stages 25. In multistage charge pump 10, the various capacitors act as energy storage elements, allowing the charge pump 10 to store and transfer charge between stages to raise the output voltage above the input voltage. As shown in FIG. 1, each non-final stage includes a set of cross-coupled transistors that toggle on and off (e.g., stage 1 includes NFETs N1 and N2 and PFETs P1 and P2) and a pair of capacitors 42 coupled to the continuous clock signals OSC_CLK and OSC_CLKB. Final stage 24 similarly includes a set of cross-coupled transistors and a pair of capacitors 44. However, because the capacitors 42 in the non-final stages 25 are charged by the continuous clocks OSC_CLK and OSC_CLKB, their capacitor values can be implemented as half of the capacitor value of the final stage capacitors 44 (which are charged by the modulated clocks). Accordingly, whereas final stage capacitors 44 have a capacitance of C, non-final stage capacitors 42 can have a capacitance of C/2. This significantly reduces the area required to implement the charge pump 10. For example, a 4.2 picofarad (pF) capacitance C would typically require an area of 500 square micrometers (0.5k um²). Since each stage has two capacitors, a charge pump with 10 non-final stages having capacitors of C/2 (e.g., 2.1 pF) would result in an area savings of about 5k um² (for capacitive loads of 100 microamps) or 50k um² (for capacitive loads of 1 microamp).

In an alternative embodiment, non-final stage capacitors 42 could be implemented with the same capacitance as the final stage capacitors 44 (e.g., C = 4.2 pF), to achieve higher efficiency. Namely, higher voltages can be achieved at the charge pump output if the full capacitance C is used for all stages. Alternatively, fewer stages could be utilized if the full capacitance C is used for all stages.

Methods and structures described herein may be implemented in and use any process of fabricating integrated circuit chips. The resulting integrated circuit chips can be distributed by the fabricator in raw wafer form (e.g., as a single wafer that has multiple unpackaged chips), as a bare die, or in a packaged form. The chip may be integrated with other chips, discrete circuit elements, and/or other signal processing devices as part of either an intermediate product or an end product. The end product can be any product that includes integrated circuit chips, such as computer products having a central processor or smartphones.

It should be understood that the terminology used herein is for the purpose of describing the disclosed structures and methods and is not intended to be limiting. For example, as used herein, the singular forms “a,” “an,” and “the” are intended to include the plural forms as well, unless the context clearly indicates otherwise. Additionally, as used herein, the terms “comprises,” “comprising,” “includes,” and/or “including” specify the presence of stated features, integers, steps, operations, elements, and/or components, but do not preclude the presence or addition of one or more other features, integers, steps, operations, elements, components, and/or groups thereof. Furthermore, as used herein, terms such as “right,” “left,” “vertical,” “horizontal,” “top,” “bottom,” “upper,” “lower,” “under,” “below,” “underlying,” “over,” “overlying,” “parallel,” “perpendicular,” etc., are intended to describe relative locations as they are oriented and illustrated in the drawings (unless otherwise indicated) and terms such as “touching,” “in direct contact,” “abutting,” “directly adjacent to,” “immediately adjacent to,” etc., are intended to indicate that at least one element physically contacts another element (without other elements separating the described elements). The term “laterally” is used herein to describe the relative locations of elements and, more particularly, to indicate that an element is positioned to the side of another element as opposed to above or below the other element, as those elements are oriented and illustrated in the drawings. For example, an element that is positioned laterally adjacent to another element will be beside the other element, an element that is positioned laterally immediately adjacent to another element will be directly beside the other element, and an element that laterally surrounds another element will be adjacent to and border the outer sidewalls of the other element. The corresponding structures, materials, acts, and equivalents of all means or step plus function elements in the claims below are intended to include any structure, material, or act for performing the function in combination with other claimed elements as specifically claimed.

The method as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various disclosed embodiments have been presented for purposes of illustration but are not intended to be exhaustive or limiting. Many modifications and variations will be apparent to those of ordinary skill in the art without departing from the scope and spirit of the disclosed embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A structure comprising:
a plurality of non-final charge pump stages coupled in series, wherein each of the non-final charge pump stages are coupled to a continuous clock; and
a final charge pump stage coupled in series to the plurality of non-final charge pump stages, wherein the final charge pump stage is coupled to a modulated clock generated from a feedback control circuit, wherein the feedback control circuit generates the modulated clock from an output of the final charge pump stage, a reference voltage, and the continuous clock.

2. The structure of claim 1, wherein the feedback control circuit includes:
a comparator that generates a compare signal from a divided voltage derived from the output of the final charge pump stage and the reference voltage; and
a logic gate arrangement that generates a modulated clock and an inverted modulated clock from the compare signal and the continuous clock.

3. The structure of claim 2, wherein the logic gate arrangement includes:
a NAND gate that generates the inverted modulated clock from the compare signal and the continuous clock; and
an inverter that generates the modulated clock from the inverted modulated clock.

4. The structure of claim 2, wherein the feedback control circuit further includes:
a voltage divider connected to receive the output of the final charge pump stage and having an output node,
wherein the voltage divider is configured to generate the divided voltage on the output node, and
wherein the comparator further includes a first input connected to the output node of the voltage divider to receive the divided voltage and a second input connected to receive the reference voltage.

5. The structure of claim 4, wherein the voltage divider includes:
a first resistor connected between the output of the final charge pump stage and the output node; and
a second resistor connected between the output node and ground.

6. The structure of claim 1, wherein the final charge pump stage is coupled to the modulated clock via a first final stage capacitor having a capacitance C.

7. The structure of claim 6, wherein each non-final charge pump stage is coupled to the continuous clock via a first non-final stage capacitor having a capacitance C/2.

8. The structure of claim 7, wherein the final charge pump stage is coupled to an inverted modulated clock via a second final stage capacitor having a capacitance C.

9. The structure of claim 8, wherein each non-final charge pump stage is coupled to an inverted continuous clock via a second non-final stage capacitor having a capacitance C/2.

10. The structure of claim 1, wherein each non-final charge pump stage and the final charge pump stage include a plurality of cross-coupled transistors.

11. The structure of claim 2, wherein the reference voltage controls an amount of fractional voltage increase provided by the final charge pump stage.

12. The structure of claim 11, wherein each non-final charge pump stage increases a voltage level to (n+1)Vin, where Vin is an input voltage level supplied to a first non-final charge pump stage and n is a relative location of each non-final charge pump stage.

13. The structure of claim 1, further comprising a memory cell coupled to the output of the final charge pump stage.

14. A method, comprising:
receiving a voltage input (Vin) at multistage charge pump having a plurality of non-final charge pump stages and a final charge pump stage, wherein the plurality of non-final charge pump stages and final charge pump stage are serially connected;
increasing a voltage at each stage n of the plurality of non-final charge pump stages according to a formula (n+1)Vin and outputting an increased voltage N*Vin to the final charge pump stage where N is a final charge pump stage number, wherein each non-final stage is coupled to a continuous clock;
increasing the voltage at the final charge pump stage with a fractional voltage R*Vin where R is any value between 0 and 1, wherein the final charge pump stage is coupled to a modulated clock generated by a feedback control circuit, and wherein the feedback control circuit generates the modulated clock from an output of the final charge pump stage, a reference voltage, and the continuous clock; and
outputting the voltage N*Vin + R*Vin.

15. The method of claim 14, wherein the feedback control circuit includes:
a comparator that generates a compare signal from a divided voltage derived from the output of the final charge pump stage and the reference voltage;
a NAND gate that generates an inverted modulated clock from the compare signal and the continuous clock; and
an inverter that generates the modulated clock from the inverted modulated clock.

16. The method of claim 14, wherein the final charge pump stage is coupled to the modulated clock and the inverted modulated clock via a pair of final stage capacitors each having a capacitance C.

17. The method of claim 16, wherein each non-final charge pump stage is coupled to the continuous clock and inverted continuous clock via a pair of non-final stage capacitors each having a capacitance C/2.

18. The method of claim 14, wherein each non-final charge pump stage and the final charge pump stage include a plurality of cross-coupled transistors.

19. The method of claim 15, wherein the voltage signal controls an amount of fractional voltage R*Vin generated by the final charge pump stage.

20. The method of claim 14, wherein the voltage N*Vin + R*Vin is output to a memory cell.
